(19) United States
(12) Patent Application Publication
(10) Pub. No.: US 2013/0346706 A1
(43) Pub. Date: Dec. 26, 2013

(54) DATA READING/WRITING METHOD AND MEMORY DEVICE

(71) Applicant: Huawei Technologies Co., Ltd., Shenzhen (CN)

(72) Inventors: Hui Lu, Santa Clara, CA (US); Tao Xiong, Chengdu (CN)

(73) Assignee: Huawei Technologies Co., Ltd., Shenzhen (CN)

(21) Appl. No.: 13/671,174

(22) Filed: Nov. 7, 2012

(30) Foreign Application Priority Data
Nov. 7, 2011 (CN) 201110348281.6

(51) Int. Cl. G11C 7/10

(52) U.S. Cl. CPC G11C 7/1075
USPC 711/149

(57) ABSTRACT

A data reading/writing method is provided and includes: determining an active memory lookup table, and a standby memory lookup table; taking a plurality of memory units as a unit, and initializing a memory unit that corresponds to each unit in the active memory lookup table and the standby memory lookup table to a different value; and when a reading operation and a writing operation exist simultaneously, and a value corresponding to a reading address is equal to a value corresponding to a writing address in the active memory lookup table, reading data from an effective single-port memory that is indicated by the reading address and in the active memory lookup table, writing data into a standby single-port memory that is indicated by the writing address and in the standby memory lookup table, and identifying single-port memories where effective data and idle data of the writing address are located.

### CROSS-REFERENCE TO RELATED APPLICATION

This application claims priority to Chinese Patent Application No. 201110348281.6, filed on Nov. 7, 2011, which is hereby incorporated by reference in its entirety.

### FIELD OF THE INVENTION

The present invention relates to the memory field, and in particular, to a data reading/writing method and a memory device.

### BACKGROUND OF THE INVENTION

In a process of designing an ASIC (Application Specific Integrated Circuit, application specific integrated circuit), a memory, such as an SRAM (Static Random Access Memory, static random access memory), and an eDRAM (Enhanced Dynamic Random Access Memory, enhanced dynamic random access memory), is usually used. According to a requirement of an access bandwidth, the memory may be categorized into a single-port memory, a pseudo-dual port memory, a dual-port memory, and a four-port memory. With the same capacity size, an access bandwidth of a pseudo-dual port/dual-port memory is twice that of a single-port memory, but the area of a pseudo-dual port/dual-port memory is more than twice that of a single-port memory.

To reduce the area of a memory, two single-port memories that have the same specification as a pseudo-dual port/dual-port memory does are generally used to achieve, through a ping-pong operation, an access bandwidth of a pseudo-dual port/dual-port memory with the same capacity size. Specifically, when only a reading operation or a writing operation exists, data may be read from two single-port memories respectively, or data is written into the two single-port memories respectively. When a reading operation and a writing operation exist simultaneously, data may be read from one single-port memory, and at the same time, data is written into the other single-port memory, thereby achieving an access bandwidth of a pseudo-dual port/dual-port memory with the same capacity size.

The inventor finds that, in comparison with a pseudo-dual port/dual-port memory with the same capacity size, the area of two single-port memories is reduced to a limited extent in the case that an access bandwidth is the same, and there is still no corresponding solution for reducing the area of the memory more significantly in the prior art.

### SUMMARY OF THE INVENTION

To reduce the area of a memory more significantly in the case of the same access bandwidth, an embodiment of the present invention provides a data reading/writing method and a memory device. The technical solutions are as follows:

A data reading/writing method includes:

according to a capacity size M×W of a to-be-achieved pseudo-dual port/dual-port memory and the number (N+1) of single-port memories, determining a capacity size (M/N)×W of the single-port memories, an active memory lookup table M×┌log₂(N+1)┐ that is used to indicate an effective single-port memory, and a standby memory lookup table (M/N)×┌log₂(N+1)┐ that is used to indicate a standby single-port memory, where

M is the depth of the pseudo-dual port/dual-port memory and represents the total number of memory units in the pseudo-dual port/dual-port memory, W is the width of the pseudo-dual port/dual-port memory and represents capacity of each memory unit, and is measured in bits, N is a positive integer, and ┌ ┐ represents rounding up to a nearest integer;

taking M/N memory units as a unit, and initializing a memory unit that corresponds to each unit in the active memory lookup table and the standby memory lookup table to a different value, where each different value is used to indicate a different single-port memory respectively; and

when a reading operation and a writing operation exist simultaneously, and a value corresponding to a reading address is equal to a value corresponding to a writing address in the active memory lookup table, reading data from an effective single-port memory that is indicated by the reading address and in the active memory lookup table, writing data into a standby single-port memory that is indicated by the writing address and in the standby memory lookup table, and identifying single-port memories where effective data and idle data of the writing address are located.

A data reading/writing method includes:

receiving a writing request, and obtaining an external address in the writing request;

according to the external address, searching an active memory lookup table for an internal address that corresponds to the external address, where the internal address includes an active memory into which write data of the writing request is to be written, and a first memory address of the write data in the active memory;

determining whether a reading request is accessing the active memory; and if a reading request is accessing a second memory address of the active memory, searching a standby memory lookup table for a first standby address that corresponds to the first memory address and in a standby memory;

writing the write data of the writing request into the first standby address;

modifying the active memory lookup table to make the first standby address correspond to the external address; and

modifying the active memory lookup table and the standby memory lookup table to make the second memory address be a standby address of the first memory address.

A memory device includes a request obtaining module, a memory address obtaining module, a reading/writing processing module, and a lookup table updating module, where

the request obtaining module is configured to receive a writing request, and obtain an external address in the writing request;

the memory address obtaining module is configured to search, according to the external address, an active memory lookup table for an internal address that corresponds to the external address, where the internal address includes an active memory into which write data of the writing request is to be written, and a first memory address of the write data in the active memory;

the memory address obtaining module is further configured to: determine whether a reading request is accessing the active memory; and if a reading request is accessing a second memory address of the active memory, search a standby memory lookup table for a first standby address that corresponds to the first memory address and in a standby memory;

the reading/writing processing module is configured to write the write data of the writing request into the first standby address; and

the lookup table updating module is configured to modify the active memory lookup table to make the first standby address correspond to the external address, and configured to modify the active memory lookup table and the standby memory lookup table to make the second memory address be a standby address of the first memory address.

A memory device includes:

(N+1) single-port memories configured to store data, one active memory lookup table used to indicate an effective single-port memory, and one standby memory lookup table used to indicate a standby single-port memory, where

a capacity size of each single-port memory is (M/N)×W, a capacity size of the active memory lookup table is M×┌log₂(N+1)┐, and a capacity size of the standby memory lookup table is (M/N)×┌log₂(N+1)┐, where

M is the depth, to-be-achieved, of a pseudo-dual port/dual-port memory and represents the total number of memory units in the pseudo-dual port/dual-port memory, W is the width of the to-be-achieved pseudo-dual port/dual-port memory and represents capacity of each memory unit, and is measured in bits, N is a positive integer, and ┌ ┐ represents rounding up to a nearest integer.

The technical solutions provided in the embodiments of the present invention bring the following benefits: with N+1 redundancy design of single-port memories, data is read from an active memory according to an indication of an active memory lookup table, and data is written into a standby memory according to an indication of a standby memory lookup table, so as to solve a conflict between reading and writing; and N+1 single-port memories with a smaller capacity size are used to achieve an access bandwidth of a pseudo-dual port/dual-port memory with the same capacity size, and meanwhile, the area of a memory is reduced significantly.

### BRIEF DESCRIPTION OF THE DRAWINGS

To describe the technical solutions in embodiments of the present invention more clearly, the accompanying drawings used for describing the embodiments are introduced briefly in the following. Apparently, the accompanying drawings in the following description are only some embodiments, and persons of ordinary skill in the art may still derive other drawings from these accompanying drawings without making creative efforts.

FIG. 1 is a flowchart of a data reading/writing method according to one aspect of an embodiment of the present invention;

FIG. 1-a is a flowchart of a reading method according to one aspect of an embodiment of the present invention;

FIG. 1-b is a flowchart of a writing method according to one aspect of an embodiment of the present invention;

FIG. 1-c is a flowchart of a data reading/writing method without a conflict of memories according to one aspect of an embodiment of the present invention;

FIG. 1-d is a flowchart of a data reading/writing method with a conflict of memories according to one aspect of an embodiment of the present invention;

FIG. 2 is a logical diagram of splicing three single-port SRAMs according to one aspect of an embodiment of the present invention;

FIG. 3 is a schematic structural diagram of a memory device according to another aspect of an embodiment of the present invention;

FIG. 4 is a flowchart of a data reading/writing method according to another aspect of an embodiment of the present invention;

FIG. 5 is a schematic structural diagram of a memory device according to another aspect of an embodiment of the present invention; and

FIG. 6 is a schematic structural diagram of a memory device according to another aspect of an embodiment of the present invention.

### DETAILED DESCRIPTION OF THE EMBODIMENTS

To make the technical solutions, objectives and merits of the present invention clearer, the embodiments of the present invention are described in the following in further detail with reference to the accompanying drawings.

In an embodiment of the present invention, capacity of a memory is represented by using an M×W manner, where M is the depth of the memory and represents the total number of memory units in the memory, and W is the width of the memory and represents capacity of each memory unit, and is also called bit width and is measured in bits. Memory capacity represented by using an M×W manner is measured in bits.

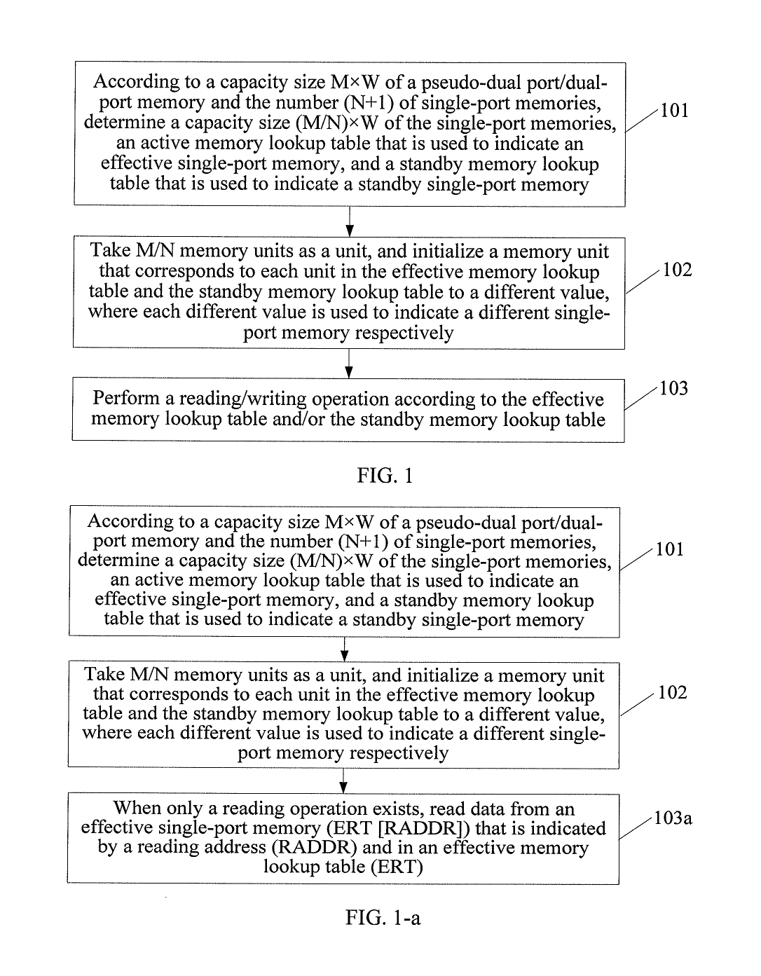

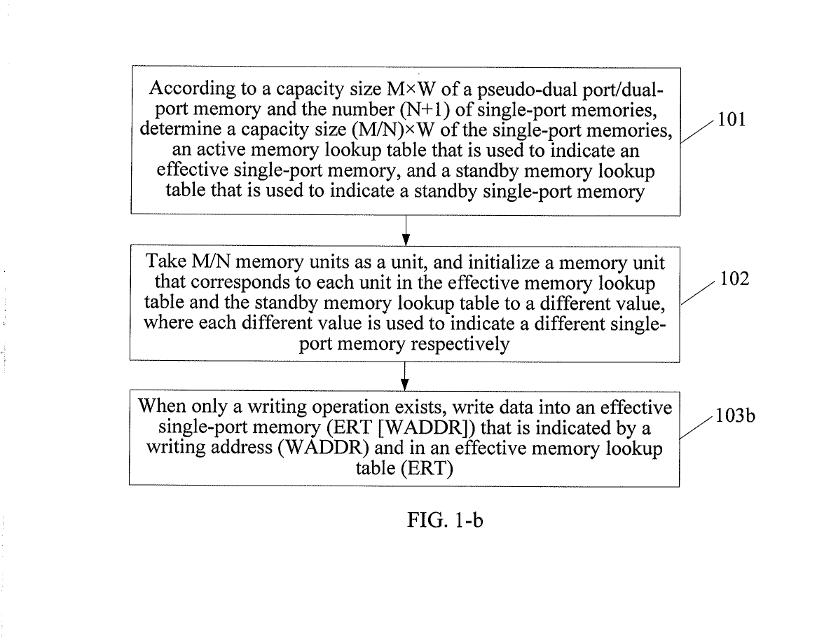

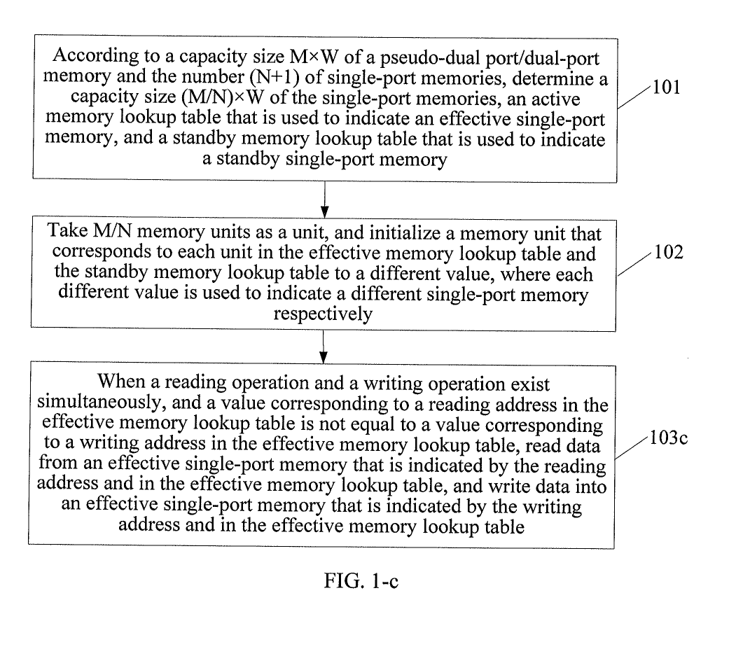

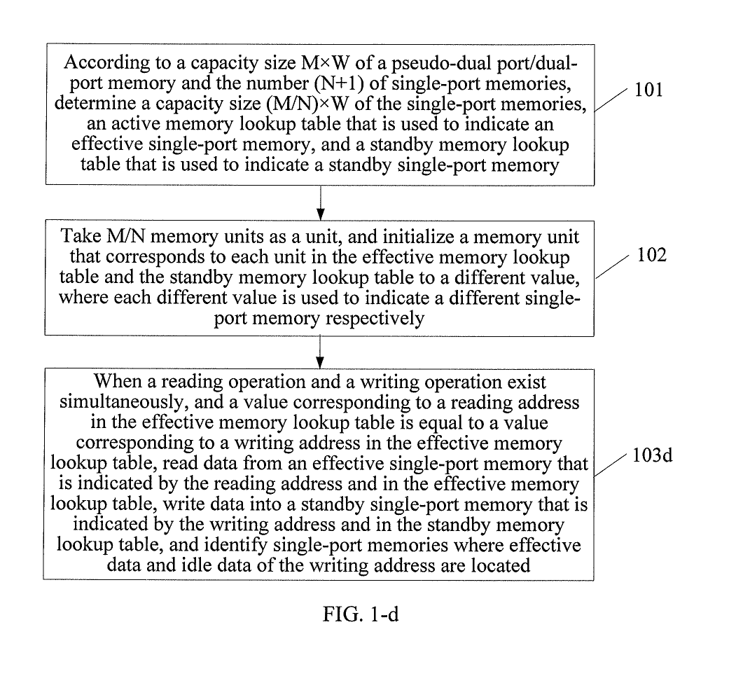

Referring to FIG. 1, one aspect of an embodiment of the present invention provides a data reading/writing method. In this method, multiple single-port memories with smaller capacity are used to achieve an access bandwidth of a pseudo-dual port/dual-port memory with larger capacity with reference to a lookup table. The method includes:

101: According to a capacity size M×W of a to-be-achieved pseudo-dual port/dual-port memory and the number (N+1) of single-port memories, determine a capacity size (MN)×W of the single-port memories, an active memory lookup table M×┌log₂(N+1)┐ that is used to indicate an effective single-port memory, and a standby memory lookup table (M/N)×┌log₂(N+1)┐ that is used to indicate a standby single-port memory, where

M is the depth of the pseudo-dual port/dual-port memory and represents the total number of memory units in the pseudo-dual port/dual-port memory, W is the width of the pseudo-dual port/dual-port memory and represents capacity of each memory unit, and is measured in bits, N is a positive integer, and ┌ ┐ represents rounding up to a nearest integer.

In this embodiment of the present invention, the active memory lookup table is set as an ERT table, the standby memory lookup table is set as an FRT table, where ERT and FRT are only symbolic representation of lookup tables, and have no physical meaning.

For example, an access bandwidth of a 32K×96 bit pseudo-dual port SRAM is to be achieved by using the following solutions. Solution 1: The access bandwidth of the 32K×96 bit pseudo-dual port SRAM may be achieved by using 2+1 16K×96 bit single-port SRAMs plus one 32K×2 bit ERT table and one 16K×2 bit FRT table. Solution 2: The access bandwidth of the 32K×96 bit pseudo-dual port SRAM may be achieved by using 4+1 8K×96 bit single-port SRAMs plus one 32K×3 bit ERT table and one 8K×3 bit FRT table. And by this analogy, N may also take another positive integer to obtain a different solution.

102: Take M/N memory units as a unit, and initialize a memory unit that corresponds to each unit in the active memory lookup table and the standby memory lookup table to a different value, where each different value is used to indicate a different single-port memory respectively.

For example, N+1 continuous M/N memory units exist in the active memory lookup table and the standby memory lookup table. Each continuous M/N memory unit is initialized to 0, 1, 2, . . . , and N in sequence to indicate a single-port memory 0, a single-port memory 1, a single-port memory 2, . . . , and a single-port memory N respectively. If N continuous M/N memory units in the active memory lookup table are initialized to 0, 1, 2, . . . , and N−1 in sequence, it indicates that effective single-port memories are 0, 1, 2, . . . , and N−1 after initialization; if one continuous M/N memory unit in the standby memory lookup table is initialized to N, it indicates that a standby single-port memory is N after initialization.

103: Perform a reading/writing operation according to the active memory lookup table and/or the standby memory lookup table, which specifically includes:

103a: Referring to FIG. 1-a, when only a reading operation exists, read data from an effective single-port memory (ERT [RADDR]) that is indicated by a reading address (RADDR) and in an active memory lookup table (ERT). A function is expressed as follows:

read_addr={ERT[RADDR],RADDR[(log₂ M/N)−1:0]},

where [(log₂ M/N)−1:0] represents an address line that corresponds to a single-port memory whose depth is M/N, and {,} represents splicing the part before the comma with the part after the comma.

103b: Referring to FIG. 1-b, when only a writing operation exists, write data into an effective single-port memory (ERT [WADDR]) that is indicated by a writing address (WADDR) and in the active memory lookup table (ERT). A function is expressed as follows:

write_addr={ERT[WADDR],WADDR[(log₂ M/N)−1:0]}.

103c: Referring to FIG. 1-c, when a reading operation and a writing operation exist simultaneously, and a value corresponding to the reading address in the active memory lookup table is not equal to a value corresponding to the writing address in the active memory lookup table, it indicates that reading and writing are effective in different single-port memories, namely, no conflict occurs between the reading and the writing.

Read data from the effective single-port memory (ERT [RADDR]) that is indicated by the reading address (RADDR) and in the active memory lookup table (ERT), and write data into the effective single-port memory (ERT [WADDR]) that is indicated by the writing address (WADDR) and in the active memory lookup table (ERT). A function is expressed as follows:

if(ERT[RADDR]≠ERT[WADDR])

read_addr={ERT[RADDR],RADDR[(log₂ M/N)−1:0]};

write_addr={ERT[WADDR],WADDR[(log₂ M/N)−1:0]}.

103d: Referring to FIG. 1-d, when a reading operation and a writing operation exist simultaneously, and a value corresponding to the reading address in the active memory lookup table is equal to a value corresponding to the writing address in the active memory lookup table, it indicates that reading and writing are effective in the same single-port memory, namely, a conflict occurs between the reading and the writing.

Read data from the effective single-port memory (ERT [RADDR]) that is indicated by the reading address (RADDR) and in the active memory lookup table (ERT), write data into a standby single-port memory (FRT [WADDR]) that is indicated by the writing address (WADDR) and in a standby memory lookup table (FRT), and identify single-port memories where effective data and idle data of the writing address are located.

The identifying the single-port memories where the effective data and idle data of the writing address are located includes:

Assign a value of the writing address (WADDR) in the standby memory lookup table (FRT) to a value of the writing address (WADDR) in the active memory lookup table (ERT) to identify a single-port memory where the effective data of the writing address (WADDR) is located; and assign a value of the reading address (RADDR) in the active memory lookup table (ERT) to a value of the writing address (WADDR) in the standby memory lookup table (FRT) to identify a single-port memory where the idle data of the writing address (WADDR) is located.

A function is expressed as follows:

if(ERT[RADDR]==ERT[WADDR]);

read_addr={ERT[RADDR],RADDR[(log₂ M/N)−1:0]};

write_addr={FRT[WADDR[(log₂ M/N)−1:0]],WADDR[(log₂ M/N)−1:0]};

ERT[WADDR]=FRT[WADDR[(log₂ M/N)−1:0]];

FRT[WADDR[(log₂ M/N)−1:0]]=ERT[RADDR].

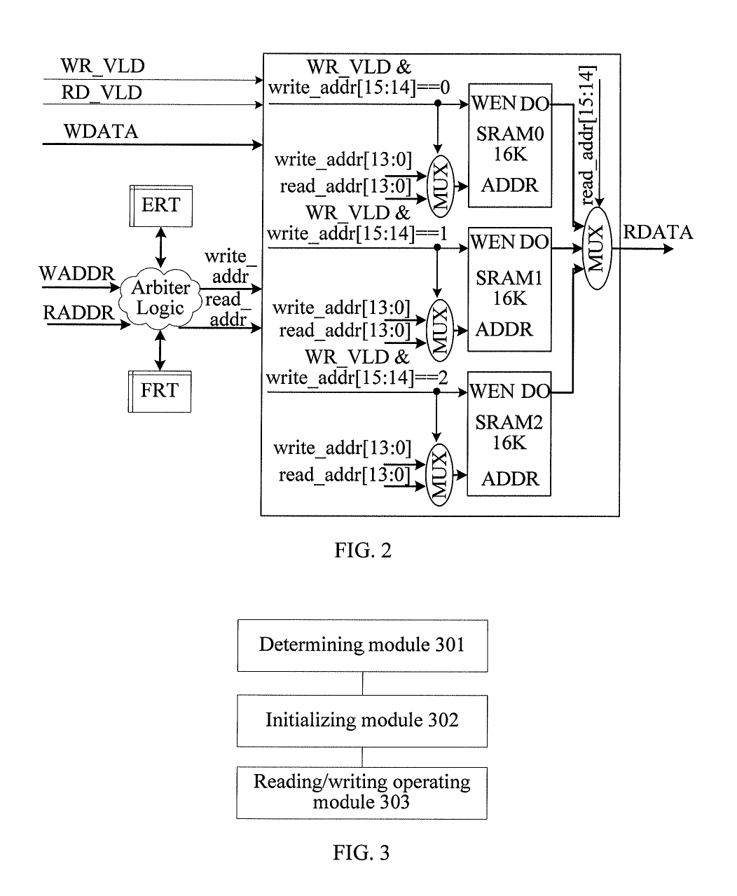

The following is an example that an access bandwidth of a 32K×96 bit pseudo-dual port SRAM may be achieved by using 2+1 16K×96 bit single-port SRAMs plus one 32K×2 bit ERT table and one 16K×2 bit FRT table. FIG. 2 is a logical diagram of splicing three single-port SRAMs (an SRAM0, an SRAM1, and an SRAM2).

1: Initialize an ERT table and an FRT table:

ERT[0˜16K−1]=0

ERT[16K˜32K−1]=1

FRT[0˜16K−1]=2

2: Read data from an address 1, and write data into an address 2. Because ERT[1]==ERT[2], a conflict occurs between reading and writing. According to an algorithm in 103d:

read_addr={ERT[1],1}={0,1}=1;

//read data from an effective SRAM0;

write_addr={FRT[2],2}={2,2}=32K+2;

//write data into a standby SRAM2;

ERT[2]=FRT[2]=2;

//identify that effective data of the address 2 is located in the SRAM2;

FRT[2]=ERT[1]=0;

//identify that idle data whose low 14 bits of an address is 2 is located in the SRAM0.

3: Read an address 16K+1, and write an address 16K+2. Because ERT[16K+1]==ERT[16K+2], a conflict occurs between reading and writing. According to the algorithm in 103d:

read_address={ERT[16K+1],1}={1,2}=16K+1;

//read data from an effective SRAM1;

write_addr={FRT[2],2}={0,2}=2;

//write data into a standby SRAM0;

ERT[16K+2]=FRT[2]=0;

identify that effective data of the address 16K+2 is located in the SRAM0;

FRT[2]=ERT[16K+1]=1;

identify that idle data whose low 14 bits of an address is 2 is located in the SRAM1.

4: Read an address 1, and write an address 16K+2. Because ERT[1]==ERT[16K+2], a conflict occurs between reading and writing. According to the algorithm in 103d:

read_addr={ERT[1]1}={0,1}=1;

//read data from an effective SRAM0;

write_addr={FRT[2],2}={1,2}=16K+1;

//write data into a standby SRAM1;

ERT[16K+2]=FRT[2]=1;

//identify that effective data of the address 16K+2 is located in the SRAM1;

FRT[2]=ERT[1]=0;

//identify that idle data whose low 14 bits of an address is 2 is located in the SRAM0.

In the foregoing instance, the algorithm ensures that one address in every 16K continuous addresses has three corresponding addresses, two of which are effective data addresses, and one is an idle data address. When a conflict occurs, an address where the idle data is located is written.

For the same specification, a saved area varies as a different value of N is selected. Selecting a proper value of N may maximize the saved area. Table 1 shows comparison of various areas achieved in an IBM 45 nm process:

TABLE 1

| | | | Rank (value of N) | | | |
|---|---|---|---|---|---|---|
| | | | 2 | 4 | 8 | 16 |
| | Type (type) | | | | | |
| | SRAM2T | SRAM1D | SRAM1D | SRAM1D | SRAM1D | SRAM1D |
| | 32K × 96 | 32K × 96 | 16K × 96 | 8K × 96 | 4K × 96 | 2K × 96 |
| Size (area of a single | 3.24 | 1.47 | 0.74 | 0.39 | 0.20 | 0.11 |
| memory) (mm²) | | | | | | |
| Instances (number) | 1 | 2 | 3 | 5 | 9 | 17 |
| Area (total area of | 3.24 | 2.94 | 2.22 | 1.95 | 1.8 | 1.87 |
| memories) (mm²) | | | | | | |
| LUT (area of a | 0 | 0.12 | 0.18 | 0.22 | 0.30 | 0.38 |
| lookup table) (mm²) | | | | | | |
| Total (total area of | 3.24 | 3.06 | 2.4 | 2.17 | 2.1 | 2.25 |
| memories and a | | | | | | |
| lookup table) (mm²) | | | | | | |
| Save (saved area) | 0% | 5.5% | 26% | 33% | 33% | 30% |

Column 1 indicates an area achieved by using one dual-port 32K×96 bit SRAM.

Column 2 indicates an area achieved by using two single-port 32K×96 bit SRAMs through a ping-pong operation.

Column 3 indicates an area achieved by using three single-port 16K×96 bit SRAMs through 2+1 redundancy.

Column 4 indicates an area achieved by using five single-port 8K×96 bit SRAMs through 4+1 redundancy.

Column 5 indicates an area achieved by using nine single-port 4K×96 bit SRAMs through 8+1 redundancy.

Column 6 indicates an area achieved by using 17 single-port 2K×96 bit SRAMs through 16+1 redundancy.

In conclusion, it can be seen that when the 8+1 redundancy is performed, the largest area may be saved.

In this embodiment of the present invention, with N+1 redundancy design of single-port memories, data is read from an active memory according to an indication of an active memory lookup table, and data is written into a standby memory according to an indication of a standby memory lookup table, so as to solve a conflict between reading and writing; and N+1 single-port memories with a smaller capacity size are used to achieve an access bandwidth of a pseudo-dual port/dual-port memory with the same capacity size, and meanwhile, the area of a memory is reduced significantly.

Referring to FIG. 3, another aspect of an embodiment of the present invention provides a memory device. The memory device uses multiple single-port memories with smaller capacity to achieve an access bandwidth of a pseudo-dual port/dual-port memory with larger capacity with reference to a lookup table. The memory device includes: a determining module 301, an initializing module 302, and a reading/writing operating module 303.

The determining module is configured to determine, according to a capacity size M×W of a to-be-achieved pseudo-dual port/dual-port memory and the number (N+1) of single-port memories, a capacity size (M/N)×W of the single-port memories, an active memory lookup table M×┌log₂(N+1)┐ that is used to indicate an effective single-port memory, and a standby memory lookup table (M/N)×┌log₂(N+1)┐ that is used to indicate a standby single-port memory, where M is the depth of the pseudo-dual port/dual-port memory and represents the total number of memory units in the pseudo-dual port/dual-port memory, W is the width of the pseudo-dual port/dual-port memory and represents capacity of each memory unit, and is measured in bits, N is a positive integer, and ┌ ┐ represents rounding up to a nearest integer.

The initializing module 302 is configured to use M/N memory units as a unit, and initialize a memory unit that corresponds to each unit in the active memory lookup table and the standby memory lookup table to a different value, where each different value is used to indicate a different single-port memory respectively.

The reading/writing operating module 303 is configured to: when a reading operation and a writing operation exist simultaneously, and a value corresponding to a reading address is equal to a value corresponding to a writing address in the active memory lookup table, read data from an effective single-port memory that is indicated by the reading address and in the active memory lookup table, write data into a standby single-port memory that is indicated by the writing address and in the standby memory lookup table, and identify single-port memories where effective data and idle data of the writing address are located.

When identifying the single-port memories where the effective data and idle data of the writing address are located, the reading/writing operating module 303 is specifically configured to:

assign a value of the writing address in the standby memory lookup table to a value of the writing address in the active memory lookup table to identify a single-port memory where the effective data of the writing address is located; and assign a value of the reading address in the active memory lookup table to a value of the writing address in the standby memory lookup table to identify a single-port memory where the idle data of the writing address is located.

The reading/writing operating module 303 is further configured to: when a reading operation and a writing operation exist simultaneously, and a value corresponding to a reading address is not equal to a value corresponding to a writing address in the active memory lookup table, read data from an effective single-port memory that is indicated by the reading address and in the active memory lookup table, and write data into an effective single-port memory that is indicated by the writing address and in the active memory lookup table.

The reading/writing operating module 303 is further configured to: when only a reading operation exists, read data from an effective single-port memory that is indicated by the reading address and in the active memory lookup table.

The reading/writing operating module 303 is further configured to: when only a writing operation exists, write data into an effective single-port memory that is indicated by the writing address and in the active memory lookup table.

In this embodiment of the present invention, with N+1 redundancy design of single-port memories, data is read from an active memory according to an indication of an active memory lookup table, and data is written into a standby memory according to an indication of a standby memory lookup table, so as to solve a conflict between reading and writing; and N+1 single-port memories with a smaller capacity size are used to achieve an access bandwidth of a pseudo-dual port/dual-port memory with the same capacity size, and meanwhile, the area of a memory is reduced significantly.

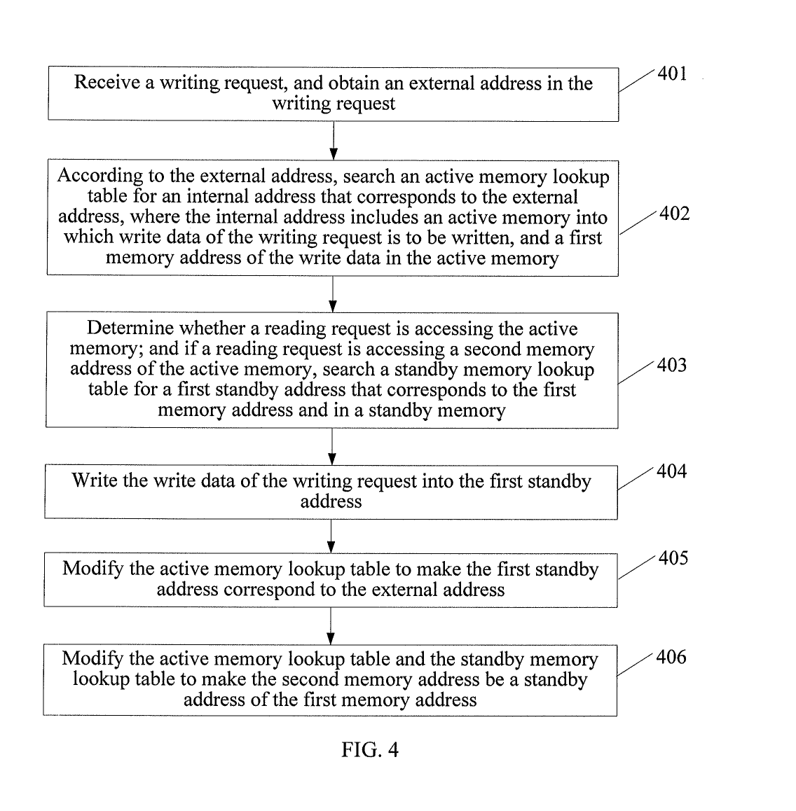

Referring to FIG. 4, another aspect of an embodiment of the present invention provides a data reading/writing method, including:

401: Receive a writing request, and obtain an external address in the writing request.

402: According to the external address, search an active memory lookup table for an internal address that corresponds to the external address, where the internal address includes an active memory into which write data of the writing request is to be written, and a first memory address of the write data in the active memory.

403: Determine whether a reading request is accessing the active memory; and if a reading request is accessing a second memory address of the active memory, search a standby memory lookup table for a first standby address that corresponds to the first memory address and in a standby memory.

404: Write the write data of the writing request into the first standby address.

405: Modify the active memory lookup table to make the first standby address correspond to the external address.

406: Modify the active memory lookup table and the standby memory lookup table to make the second memory address be a standby address of the first memory address.

Further, the method further includes: if the reading request is accessing a third memory address of another active memory other than the active memory, writing the write data of the writing request into the first memory address, and reading data from the third memory address.

In this embodiment of the present invention, when a reading operation and a writing operation exist simultaneously on the same memory, write data of a writing request is written into a standby address through redundancy design of a memory, thereby solving a conflict between reading and writing.

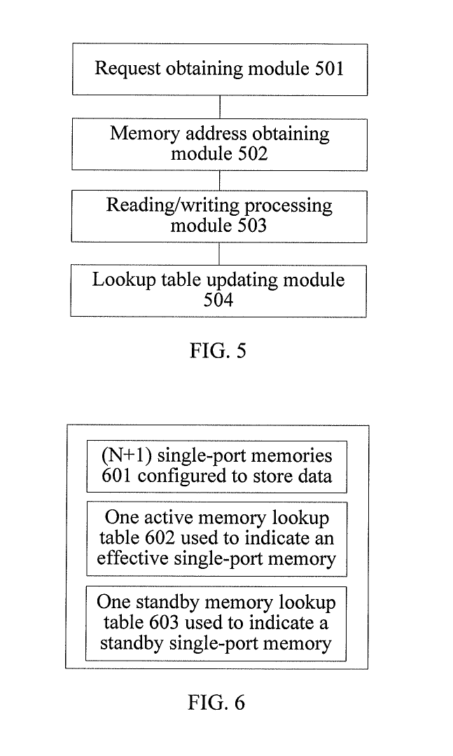

Referring to FIG. 5, another aspect of an embodiment of the present invention provides a memory device, including a request obtaining module 501, a memory address obtaining module 502, a reading/writing processing module 503, and a lookup table updating module 504.

The request obtaining module 501 is configured to receive a writing request, and obtain an external address in the writing request.

The memory address obtaining module 502 is configured to search, according to the external address, an active memory lookup table for an internal address that corresponds to the external address, where the internal address includes an active memory into which write data of the writing request is to be written, and a first memory address of the write data in the active memory.

The memory address obtaining module 502 is further configured to: determine whether a reading request is accessing the active memory; and if a reading request is accessing a second memory address of the active memory, search a standby memory lookup table for a first standby address that corresponds to the first memory address and in a standby memory.

The reading/writing processing module 503 is configured to write the write data of the writing request into the first standby address.

The lookup table updating module 504 is configured to modify the active memory lookup table to make the first standby address correspond to the external address, and modify the active memory lookup table and the standby memory lookup table to make the second memory address be a standby address of the first memory address.

Further, the reading/writing processing module 503 is further configured to: if the reading request is accessing a third memory address of another active memory other than the active memory, write the write data of the writing request into the first memory address, and read data from the third memory address.

In this embodiment of the present invention, when a reading operation and a writing operation exist simultaneously on the same memory, write data of a writing request is written into a standby address through redundancy design of a memory, thereby solving a conflict between reading and writing.

Referring to FIG. 6, another aspect of an embodiment of the present invention provides a memory device, including:

(N+1) single-port memories 601 configured to store data, one active memory lookup table 602 used to indicate an effective single-port memory, and one standby memory lookup table 603 used to indicate a standby single-port memory, where

a capacity size of each single-port memory is (M/N)×W, a capacity size of the active memory lookup table is M×┌log₂(N+1)┐, and a capacity size of the standby memory lookup table is (M/N)×┐log₂(N+1)┐, where

M is the depth, to-be-achieved, of a pseudo-dual port/dual-port memory and represents the total number of memory units in the pseudo-dual port/dual-port memory, W is the width of the to-be-achieved pseudo-dual port/dual-port memory and represents capacity of each memory unit, and is measured in bits, N is a positive integer, and ┌ ┐ represents rounding up to a nearest integer.

Further, M/N memory units are taken as a unit, and a memory unit that corresponds to each unit in the active memory lookup table and the standby memory lookup table is initialized to a different value, where each different value is used to indicate a different single-port memory respectively.

In this embodiment of the present invention, with N+1 redundancy design of single-port memories, data is read from an active memory according to an indication of an active memory lookup table, and data is written into a standby memory according to an indication of a standby memory lookup table, so as to solve a conflict between reading and writing; and N+1 single-port memories with a small capacity size are used to achieve an access bandwidth of a pseudo-dual port/dual-port memory with the same capacity size, and meanwhile, the area of a memory is reduced significantly.

Persons of ordinary skill in the art may understand that all or a part of the steps of the foregoing embodiments of the present invention may be implemented by hardware, and may also be implemented by a program instructing relevant hardware. The program may be stored in a computer readable storage medium. The foregoing storage medium may be a read-only memory, a magnetic disk, or an optical disk.

The foregoing descriptions are merely exemplary embodiments of the present invention, but are not intended to limit the present invention. Any modification, equivalent replacement, and improvement that are made without departing from the spirit and principle of the present invention shall all fall within the protection scope of the present invention.

What is claimed is:

1. A data reading/writing method, comprising:
according to a capacity size M×W of a to-be-achieved pseudo-dual port/dual-port memory and the number (N+1) of single-port memories, determining a capacity size (M/N)×W of the single-port memories, an active memory lookup table M×┌log₂(N+1)┐ that is used to indicate an effective single-port memory, and a standby memory lookup table (M/N)×┌log₂(N+1)┐ that is used to indicate a standby single-port memory, wherein
M is the depth of the pseudo-dual port/dual-port memory and represents the total number of memory units in the pseudo-dual port/dual-port memory, W is the width of the pseudo-dual port/dual-port memory and represents capacity of each memory unit, and is measured in bits, N is a positive integer, and ┌ ┐ represents rounding up to a nearest integer;
taking M/N memory units as a unit, and initializing a memory unit that corresponds to each unit in the active memory lookup table and the standby memory lookup table to a different value, where each different value is used to indicate a different single-port memory respectively; and
when a reading operation and a writing operation exist simultaneously, and a value corresponding to a reading address is equal to a value corresponding to a writing address in the active memory lookup table, reading data from an effective single-port memory that is indicated by the reading address and in the active memory lookup table, writing data into a standby single-port memory that is indicated by the writing address and in the standby memory lookup table, and identifying single-port memories where effective data and idle data of the writing address are located.

2. The method according to claim 1, wherein:
the identifying the single-port memories where the effective data and idle data of the writing address are located comprises:
assigning a value of the writing address in the standby memory lookup table to a value of the writing address in the active memory lookup table to identify a single-port memory where the effective data of the writing address is located; and assigning a value of the reading address in the active memory lookup table to a value of the writing address in the standby memory lookup table to identify a single-port memory where the idle data of the writing address is located.

3. The method according to claim 1, further comprising:
when a reading operation and a writing operation exist simultaneously, and a value corresponding to a reading address is not equal to a value corresponding to a writing address in the active memory lookup table, reading data from an effective single-port memory that is indicated by the reading address and in the active memory lookup table, and writing data into an effective single-port memory that is indicated by the writing address and in the active memory lookup table.

4. The method according to claim 1, further comprising:
when only a reading operation exists, reading data from an effective single-port memory that is indicated by the reading address and in the active memory lookup table.

5. The method according to claim 1, further comprising:
when only a writing operation exists, writing data into an effective single-port memory that is indicated by the writing address and in the active memory lookup table.

6. A data reading/writing method, comprising:
receiving a writing request, and obtaining an external address in the writing request;
according to the external address, searching an active memory lookup table for an internal address that corresponds to the external address, wherein the internal address comprises an active memory into which write data of the writing request is to be written, and a first memory address of the write data in the active memory;
determining whether a reading request is accessing the active memory; and if a reading request is accessing a second memory address of the active memory, searching a standby memory lookup table for a first standby address that corresponds to the first memory address and in a standby memory;
writing the write data of the writing request into the first standby address;
modifying the active memory lookup table to make the first standby address correspond to the external address; and
modifying the active memory lookup table and the standby memory lookup table to make the second memory address be a standby address of the first memory address.

7. The method according to claim 6, further comprising:
if the reading request is accessing a third memory address of another active memory other than the active memory, writing the write data of the writing request into the first memory address, and reading data from the third memory address.

8. A memory device, comprising a request obtaining module, a memory address obtaining module, a reading/writing processing module, and a lookup table updating module, wherein the request obtaining module is configured to receive a writing request, and obtain an external address in the writing request;
the memory address obtaining module is configured to search, according to the external address, an active memory lookup table for an internal address that corresponds to the external address, wherein the internal address comprises an active memory into which write data of the writing request is to be written, and a first memory address of the write data in the active memory;
the memory address obtaining module is further configured to: determine whether a reading request is accessing the active memory; and if a reading request is accessing a second memory address of the active memory, search a standby memory lookup table for a first standby address that corresponds to the first memory address and in a standby memory;
the reading/writing processing module is configured to write the write data of the writing request into the first standby address; and
the lookup table updating module is configured to modify the active memory lookup table to make the first standby address correspond to the external address, and modify the active memory lookup table and the standby memory lookup table to make the second memory address be a standby address of the first memory address.

9. The memory device according to claim 8, wherein:
the reading/writing processing module is further configured to: if the reading request is accessing a third memory address of another active memory other than the active memory, write the write data of the writing request into the first memory address, and read data from the third memory address.

10. A memory device, comprising:
(N+1) single-port memories configured to store data, one active memory lookup table used to indicate an effective single-port memory, and one standby memory lookup table used to indicate a standby single-port memory, wherein
a capacity size of each single-port memory is (M/N)×W, a capacity size of the active memory lookup table is M×┌log₂(N+1)┐, and a capacity size of the standby memory lookup table is (M/N)×┌log₂(N+1)┐,
M is the depth, to-be-achieved, of a pseudo-dual port/dual-port memory and represents the total number of memory units in the pseudo-dual port/dual-port memory, W is the width of the to-be-achieved pseudo-dual port/dual-port memory and represents capacity of each memory unit, and is measured in bits, N is a positive integer, and ┌ ┐ represents rounding up to a nearest integer.

11. The memory device according to claim 10, wherein:
M/N memory units are taken as a unit, and a memory unit that corresponds to each unit in the active memory lookup table and the standby memory lookup table is initialized to a different value, wherein each different value is used to indicate a different single-port memory respectively.
